(19) United States
(12) Patent Application Publication
(10) Pub. No.: US 2026/0241512 A1
(43) Pub. Date: Aug. 20, 2026

(54) GRINDING APPARATUS, INCLINATION ADJUSTING METHOD, AND INFORMATION DISPLAY

(71) Applicant: Tokyo Electron Limited, Tokyo (JP)

(72) Inventors: Nobutaka FUKUNAGA, Kikuchi-gun, Kumamoto (JP); Masakazu YARIMITSU, Kikuchi-gun, Kumamoto (JP)

(21) Appl. No.: 19/155,960

(22) PCT Filed: Feb. 1, 2024
(86) PCT No.: PCT/JP2024/003246

§ 371 Date: Aug. 13, 2025

(30) Foreign Application Priority Data
Feb. 14, 2023 (JP) 2023-021154

(51) Int. Cl. B24B 47/22; B24B 49/00; H10P 72/00

(52) U.S. Cl. CPC B24B 47/22; B24B 49/00; H10P 72/0428

(57) ABSTRACT

A grinding apparatus configured to grind a substrate includes a substrate holder configured to hold the substrate on a holding surface thereof; a grinding device configured to grind the substrate, which is held by the substrate holder, with a grinding surface thereof; an inclination adjusting device configured to adjust a relative inclination between the holding surface and the grinding surface; and an information display configured to input and display information regarding shape correction of the substrate. The information display displays a display area in which an expected grinding shape of the substrate ground by the grinding device is displayed based on thickness information of the substrate before correction and correction pattern information.

### TECHNICAL FIELD

The various aspects and embodiments described herein pertain generally to a grinding apparatus, an inclination adjusting method, and an information display.

### BACKGROUND

Patent document 1 discloses a grinding apparatus that grinds a plate-shaped workpiece on a holding table, using a grinding device. This grinding apparatus is equipped with at least three measuring devices that measure a distance between the holding table and a base, measures a thickness distribution of the plate-shaped workpiece based on at least three measured distances obtained by the measuring devices, and determines whether the plate-shaped workpiece has been ground to a uniform thickness.

### Prior Art Document

Patent Document 1: Japanese Patent Laid-open Publication No. 2015-009295

### DISCLOSURE OF THE INVENTION

### Problems to be Solved by the Invention

Exemplary embodiments provide a grinding apparatus capable of verifying an expected shape of a substrate after grinding.

### Means for Solving the Problems

In an exemplary embodiment, a grinding apparatus configured to grind a substrate includes a substrate holder configured to hold the substrate on a holding surface thereof; a grinding device configured to grind the substrate, which is held by the substrate holder, with a grinding surface thereof; an inclination adjusting device configured to adjust a relative inclination between the holding surface and the grinding surface; and an information display configured to input and display information regarding shape correction of the substrate. The information display displays a display area in which an expected grinding shape of the substrate ground by the grinding device is displayed based on thickness information of the substrate before correction and correction pattern information.

### Effect of the Invention

According to the exemplary embodiments, it is possible to provide the grinding apparatus capable of verifying the expected shape of the substrate after grinding.

### BRIEF DESCRIPTION OF THE DRAWINGS

FIG. 1 is a plan view illustrating a schematic configuration of a grinding apparatus according to an exemplary embodiment.

FIG. 2 is a side view illustrating a configuration example of a grinding device and a chuck.

FIG. 3 is an explanatory diagram illustrating an example of measurement points by a thickness measuring device.

FIG. 4 is an explanatory diagram illustrating a state in which a wafer is being ground by the grinding device.

FIG. 5 is an explanatory diagram illustrating a display example of a display panel according to the present exemplary embodiment.

FIG. 6 is a flowchart showing a processing sequence of a wafer processing by the grinding apparatus.

FIG. 7 is a flowchart showing a flow of a shape correction operation by the grinding apparatus.

FIG. 8 is an explanatory diagram illustrating another display example of the display panel.

### DETAILED DESCRIPTION

In a semiconductor manufacturing process, a semiconductor substrate (hereafter, referred to as “wafer”) is ground to be thinned. The grinding of the wafer is performed by bringing a grinding surface of a grinding whetstone into contact with the wafer held on a holding surface of a chuck, while rotating the chuck.

In the grinding of the wafer, the holding surface of the chuck and the grinding surface of the grinding whetstone are adjusted to be parallel to each other to ensure that the in-surface thickness of the wafer as a product is uniform. Patent Document 1 describes the grinding apparatus for grinding the plate-shaped workpiece (wafer), in which if the plate-shaped workpiece is not ground to a uniform thickness, a distance between the holding table (chuck) and the base is adjusted so that a top surface of the holding table and a bottom surface of the grinding whetstone are parallel to each other.

However, in the grinding apparatus described in Patent Document 1, even after adjusting the distance between the holding table and the base, it may be difficult to display a shape of the plate-shaped workpiece after being ground by the grinding apparatus that has been adjusted. In particular, when it is required to process the plate-shaped workpiece into a shape other than a flat shape, it has been difficult to predict an actual shape of the plate-shaped workpiece after being subjected to the grinding, and there has been a risk of discrepancy between an expected grinding shape and the actual shape.

In view of the foregoing, the present disclosure provides a grinding apparatus capable of verifying an expected shape of a substrate after grinding. Hereinafter, a grinding apparatus according to an exemplary embodiment and a method of adjusting an inclination between a holding surface and a grinding surface performed by using the grinding apparatus will be described with reference to the accompanying drawings. In the present specification and the drawings, parts having substantially the same functions and configurations will be assigned the same reference numerals, and redundant descriptions thereof will be omitted.

In the technology disclosed herein, “grinding” of the wafer W includes so-called “polishing”. Therefore, although the following description will be provided for “grinding apparatus” as an example, the technology disclosed herein may also be applicable to “polishing apparatus”.

A grinding apparatus 1 has a configuration in which a carry-in/out station 2 and a processing station 3 are connected as a single structure. In the carry-in/out station 2, a cassette C capable of accommodating a multiple number of wafers W is carried to/from, for example, the outside. The processing station 3 is equipped with various types of processing devices each configured to perform a required processing on the wafer W.

The carry-in/out station 2 is provided with a cassette placement table 10. Also, a wafer transfer area 20 is provided adjacent to the cassette placement table 10 on the positive Y-axis side of the cassette placement table 10.

In the wafer transfer area 20, there is provided a wafer transfer device 22 configured to be movable on a transfer path 21. The wafer transfer device 22 has a transfer fork 23 that holds and transfers the wafer W. The wafer transfer device 22 is configured to be capable of transferring the wafer W to/from the cassette C on the cassette placement table 10, an alignment device 50 to be described later, and a first cleaning device 60 to be described later.

In the processing station 3, a processing such as grinding or cleaning is performed on the wafer W. The processing station 3 has a transfer device 30 that transfers the wafer W, a grinding module 40 that grinds the wafer W, the alignment device 50 that adjusts a direction of the horizontal direction in the wafer W, and the first cleaning device 60 and a second cleaning device 70 that clean the wafer W after being ground.

The transfer device 30 is a multi-joint robot equipped with a plurality of, for example, three arms 31. Each of the three arms 31 is configured to be pivotable. A transfer pad 32 that attracts and holds the wafer W is mounted to the arm 31 at a leading end. The arm 31 at a base end is mounted to an elevating mechanism 33 that raises and lowers the arm 31 in the vertical direction. The transfer device 30 is configured to be able to transfer the wafer W to/from the grinding module 40, the alignment device 50, the first cleaning device 60, and the second cleaning device 70.

The grinding module 40 has a rotary table 41. On the rotary table 41, four chucks 42a to 42d (hereinafter, these may be collectively referred to as “chuck 42”) that attract and hold the wafer W are provided. By way of example, a porous chuck is used as the chuck 42. A surface of the chuck 42, i.e., a holding surface for the wafer W, has a convex shape with a central portion protruding higher than an edge portion when viewed from the side. This protrusion of the central portion is actually minute, but in the illustration of the explanation below, the protrusion of the central portion of the chuck 42 is rather exaggerated for the clarity of explanation.

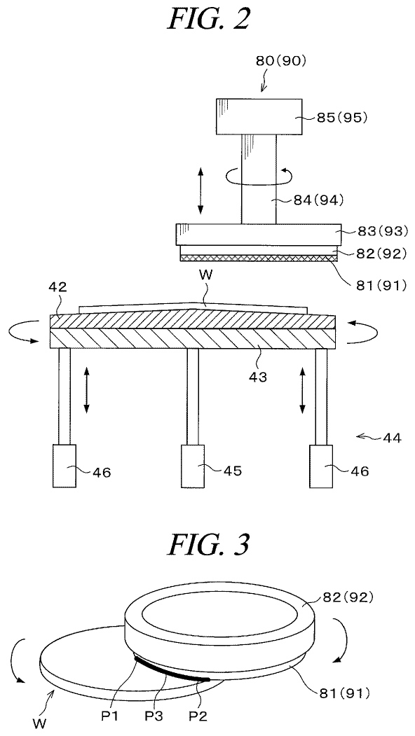

As shown in FIG. 2, the chuck 42 as a substrate holder is held by a chuck base 43. The chuck base 43 is provided with an inclination adjusting device 44 configured to adjust a relative inclination between a grinding device 80 (90) to be described later and the chuck 42. The inclination adjusting device 44 has a fixed shaft 45 provided on a bottom surface of the chuck base 43 and a plurality of, for example, two elevating shafts 46. Each elevating shaft 46 is configured to be extensible and contractible, and serves to move the chuck base 43 up and down. The inclination adjusting device 44 raises and lowers one end of an outer periphery of the chuck base 43 in the vertical direction by the elevating shafts 46 with respect to the other end (the position corresponding to the fixed shaft 45), thereby allowing the chuck 42 and the chuck base 43 to be inclined. This allows a relative inclination between a grinding surface of the grinding device 80 (90) at a processing position B1 (B2) to be described later and a surface (holding surface) of the chuck 42 to be adjusted.

Further, the configuration of the inclination adjusting device 44 is not limited to the above, and any of various configurations may be adopted as long as the relative angle (parallelism) of the surface (holding surface) of the chuck 42 with respect to the grinding surface of each grinding device can be adjusted.

The four chucks 42a to 42d can be moved to delivery positions A1 and A2 and the processing positions B1 and B2 by the rotation of the rotary table 41. In addition, each of the four chucks 42a to 42d is configured to be rotatable around a vertical axis by a non-illustrated rotating mechanism.

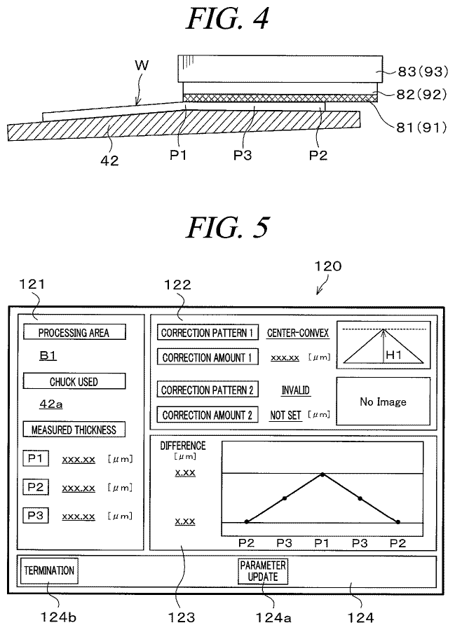

At the delivery position A1 (A2), the wafer W is delivered onto the chuck 42 by the transfer device 30. A thickness measuring device 100 configured to measure the thickness of the wafer W after being ground at the processing position B1 (B2) is provided at the delivery positions A1 and A2. The thickness measuring device 100 is provided with a sensor (not shown) that measures the thickness of the wafer W at at least two points (in the present exemplary embodiment, three points (see FIG. 3 and FIG. 4): a center point P1, an outer periphery point P2, and a radial midpoint P3 between the center point P1 and the outer periphery point P2).

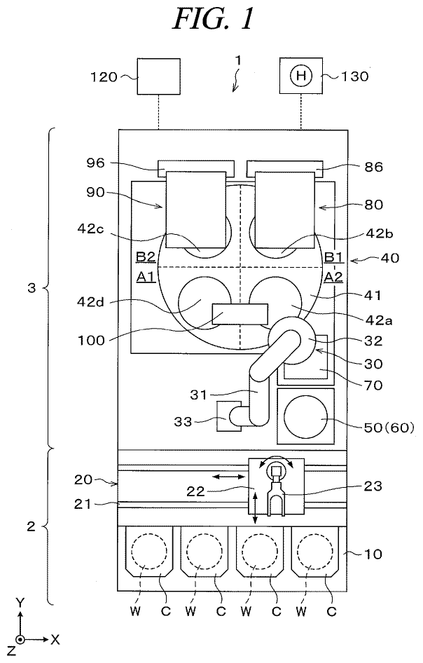

As shown in FIG. 1, the present exemplary embodiment will be described for an example case where the thickness measuring device 100 is provided at the delivery positions A1 and A2, but the location of the thickness measuring device 100 is not limited thereto. As a specific example, the thickness measuring device 100 may be disposed at the processing positions B1 and B2, or may be disposed separately from the grinding module 40. In the latter case, the transfer device 30 may be configured to transfer the wafer W after being ground to the thickness measuring device 100 disposed separately from the grinding module 40. As still another example, the thickness measuring device 100 may be disposed outside the grinding apparatus 1.

The grinding devices 80 and 90 are disposed at the processing positions B1 and B2, respectively, and each serves to grind the wafer W held by the chuck 42.

As illustrated in FIG. 2, the grinding device 80 includes a grinding wheel 82 having an annular grinding whetstone 81 on a bottom surface thereof, a mount 83 supporting the grinding wheel 82, a spindle 84 that rotates the grinding wheel 82 via the mount 83, and a driver 85 having, for example, a non-illustrated motor embedded therein. Also, the grinding device 80 is configured to be movable in the vertical direction along a supporting column 86 shown in FIG. 1.

As depicted in FIG. 2, the grinding device 90 has the same configuration as the grinding device 80. That is, the grinding device 90 has a grinding wheel 92 equipped with an annular grinding whetstone 91, a mount 93, a spindle 94, a driver 95, and a supporting column 96.

Here, as stated above, the holding surface of the chuck 42 has a convex shape. Therefore, in the grinding of the wafer W using the grinding device 80 (90), a part of the annular grinding whetstone 81 (91) comes into contact with the wafer W as shown by a bold line in FIG. 3 and FIG. 4. More specifically, the annular grinding whetstone 81 (91) comes into contact with the wafer W in an arcuate line shape from a center to an outer edge of the wafer W. In this state, by rotating the chuck 42 and the grinding wheel 82 (92), the entire surface of the wafer W is ground.

In addition, in the grinding device 80 (90), the aforementioned inclination adjusting device 44 adjusts a relative angle (inclination) between the holding surface of the chuck 42 and the grinding surface of the grinding whetstone 81 (91), so that a shape of the wafer W after being ground (hereinafter, sometimes referred to as “grinding shape” of the wafer W) may be controlled to any one of a flat shape, a center-convex shape, a center-concave shape, a W-shape, an M-shape, and a combination of any two of these shapes. The flat shape refers to a form in which the entire surface of the wafer W is adjusted to have a flatness (total thickness variation (TTV)) equal to or less than a required level, and desirably, a form in which the thickness of the wafer W is uniform across the entire surface thereof. The center-convex shape refers to a form in which a thickness value at the center point P1 of the wafer W is greater than that at the outer periphery point P2. The center-concave shape refers to a form in which the thickness value at the center point P1 is smaller than that at the outer periphery point P2. The W-shape refers to a form in which a thickness value at the radial midpoint P3 of the wafer W is smaller than the thickness values at the center point P1 and the outer periphery point P2. The M-shape refers to a form in which the thickness value at the radial midpoint P3 is greater than the thickness values at the center point P1 and the outer periphery point P2 of the wafer W.

The grinding apparatus 1 described above is equipped with a display panel 120. The display panel 120 is, by way of non-limiting example, a monitor or a touch panel, and may be directly mounted to the grinding apparatus 1 or may be monitored remotely.

As shown in FIG. 5, the display panel 120 as an information display displays a first input area 121, a second input area 122, a display area 123, and an instruction area 124 on a single screen.

Information of the wafer W after being ground by the grinding apparatus 1 is input into the first input area 121. Based on the grinding shape (thickness) of the wafer W after being ground, whose information has been input into the first input area 121, information for setting and correcting a grinding shape of a wafer W to be processed next (hereinafter, sometimes referred to as “second wafer W”) by the same chuck 42 and the same grinding device in the grinding apparatus 1 is input into the second input area 122. The display area 123 displays, based on the information input in the first input area 121 and the second input area 122, an expected grinding shape of the second wafer W to be ground by the griding apparatus 1 after the correction.

The instruction area 124 includes a parameter update section 124a and a termination section 124b. The parameter update section 124a calculates, based on an operator's selection, an inclination of the inclination adjusting device 44 (a relative angle between the holding surface of the chuck 42 and the grinding surface of the grinding whetstone 81 (91)) to achieve the expected grinding shape displayed in the display area 123. Using the calculated inclination information of the inclination adjusting device 44, the parameter update section 124a updates internal parameters for correcting the grinding shape, etc.. The termination section 124b terminates, based on the operator's selection, the operations of setting and correcting the grinding shape through the display panel 120.

Details of the elements that are input to or displayed on the display panel 120, the setting and correcting of the shape of the next wafer W performed using the display panel 120, the operation of adjusting the inclination between the grinding surface and the holding surface, and so forth will be described later.

Further, the above-described grinding apparatus 1 is provided with at least one controller 130. The controller 130 executes computer-executable instructions that cause the grinding apparatus 1 to perform various processes described in the present disclosure. The controller 130 may be configured to control the individual components of the grinding apparatus 1 to perform the various processes described herein. In one exemplary embodiment, a part or the whole of the controller 130 may be included in the grinding apparatus 1. The controller 130 may include a processor, a storage, and a communication interface. The controller 130 may be implemented by, for example, a computer. The processor may be configured to read out from the storage a program that provides logic or routines that enable various control operations to be performed, and to perform the various control operations by executing the read-out program. This program includes a program that controls the operation of adjusting the inclination between the grinding surface and the holding surface, which will be described later, and so forth. This program may be stored in the storage in advance, or may be acquired via a medium when necessary. The acquired program is stored in the storage, and is read from the storage by the processor to be executed. The medium may be any computer-readable recording medium H, or a communication line connected to the communication interface. The recording medium H may be transitory or non-transitory. The processor may be a central processing unit (CPU). The storage may include a random access memory (RAM), a read only memory (ROM), a hard disk drive (HDD), a solid state drive (SSD), or a combination thereof. The communication interface may communicate with the grinding apparatus 1 via a communication line such as a local area network (LAN).

Although the grinding apparatus 1 according to the present exemplary embodiment is configured as described above, it should be noted that the exemplary embodiment disclosed herein is illustrative in all aspects and is not anyway limiting. The above-described exemplary embodiment may be omitted, replaced and modified in various ways without departing from the scope and the spirit of claims.

For example, in the above-described exemplary embodiment, the so-called dual-axis grinding module 40 having the two grinding devices 80 and 90 is adopted in the grinding apparatus 1. However, the configuration of the grinding module 40 is not limited thereto. Specifically, the grinding module 40 may have a single-axis configuration with only one grinding device, or a triple-axis configuration with three grinding devices for sequentially performing rough grinding, intermediate grinding, and finish grinding. Alternatively, even with the dual-axis configuration as illustrated, the grinding module 40 may be configured to sequentially perform the rough grinding and the finish grinding on the same wafer W, rather than performing the grinding on different wafers W as in the present exemplary embodiment.

Further, the number of the chucks 42 disposed in the grinding module 40 is not particularly limited, and one or more chucks 42 may be appropriately arranged depending on the configuration or number of the grinding devices provided.

Furthermore, the information input to or displayed on the display panel 120 is not limited to the examples described above, and any information may be input or displayed.

Next, a series of processes of a wafer processing performed in the grinding apparatus 1 will be explained. In the grinding module 40 of the grinding apparatus 1, the wafer W is held by one of the four chucks 42, and a grinding processing of the wafer W is performed using either one of the grinding devices 80 and 90, independently. Here, the same grinding processing is performed regardless of which combination of the chuck 42 and the grinding device is adopted. Therefore, the following description will be provided for an example case where the wafer W is held by the chuck 42a among the four chucks 42 and ground by the grinding device 80. Further, in the description that follows, the combination of the chuck 42 and the grinding device may be referred to as “grinding condition” of the wafer W.

First, the cassette C accommodating the multiple number of wafers W is placed on the cassette placement table 10 of the carry-in/out station 2. Next, the wafer W in the cassette C is taken out by the transfer fork 23 of the wafer transfer device 22 and transferred to the processing station 3. The wafer W transferred to the processing station 3 is delivered to the alignment device 50. In the alignment device 50, the direction of the horizontal direction in the wafer W is adjusted.

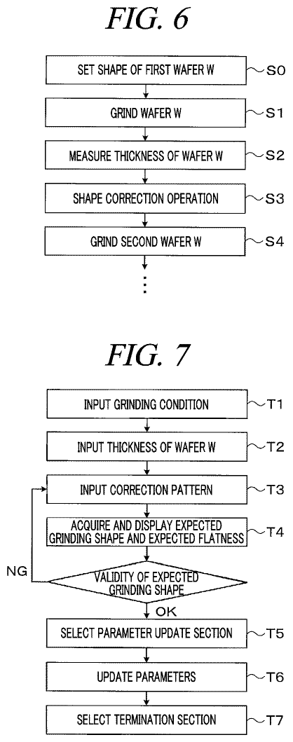

Next, the wafer W is transferred from the alignment device 50 to the grinding module 40 and delivered to the chuck 42a at the delivery position A1 by the transfer device 30. Thereafter, the rotary table 41 is rotated to move the wafer W to the processing position B1. Then, the wafer W is ground by the grinding device 80 (S1 in FIG. 6).

In the grinding processing of the wafer W in the grinding device 80, a target shape of the wafer W to be subjected to the grinding processing by the grinding device 80 for the first time, that is, a grinding shape of the wafer W after grinding is set prior to the grinding processing (S0 in FIG. 6). Specifically, a pattern of the target grinding shape of the wafer W after grinding and a corresponding correction amount are input into the second input area 122 of the display panel 120. Details of the information input to the display panel 120 will be described later.

Next, the rotary table 41 is rotated to move the wafer W to the delivery position A1. At the delivery position A1, the thickness measuring device 100 measures the thickness of the wafer W after being ground by the grinding device 80 at at least two points, in the present exemplary embodiment, at three points including the center point P1, the outer periphery point P2, and the radial midpoint P3 shown in FIG. 3 and FIG. 4 (S2 in FIG. 6).

Subsequently, in the grinding apparatus 1, the relative inclination between the bottom surface (grinding surface) of the grinding whetstone 81 and the top surface (holding surface) of the chuck 42a during the grinding of the second wafer W is adjusted based on the thickness of the wafer W measured by the thickness measuring device 100 so as to improve the thickness distribution and/or flatness of the second wafer W (S3 in FIG. 6). Hereinafter, the operation related to the inclination adjustment in the process S3 may be referred to as “shape correction operation”.

In the grinding device 80 of the grinding apparatus 1, the grinding environment between the grinding device 80 and the chuck 42 varies for each individual wafer W due to various factors such as wear of the grinding whetstone 81 during the grinding processing. In other words, there is a risk that the flatness of the wafer W after the grinding by the grinding device 80 may fluctuate from one wafer to another. To address this, in the technology disclosed herein, the aforementioned shape correction operation is performed each time a wafer W is ground, thereby suppressing the unevenness in flatness, etc., caused by the wear of the grinding whetstone 81 or the like.

The wafer W after being ground is transferred by the transfer device 30 to the first cleaning device 60 and/or the second cleaning device 70. In the first cleaning device 60 and the second cleaning device 70, the front and/or rear surface of the wafer W after being ground is cleaned.

Thereafter, the wafer W that has been cleaned after the grinding is transferred by the transfer fork 23 of the wafer transfer device 22 to the cassette C of the cassette placement table 10, and after all the wafers W in the cassette C have been processed, the cassette C is taken out from the grinding apparatus 1.

In addition, in the grinding apparatus 1, a grinding processing of the second wafer W is performed using the same combination of the chuck 42 and the grinding device (the chuck 42a and the grinding device 80 in this exemplary embodiment) as used to process the wafer W in the state where the shape correction operation described above has been performed (S4 in FIG. 6). In this way, since the grinding of the second wafer W is performed in the state where the relative inclination of the grinding surface and the holding surface has been adjusted, the thickness distribution and/or flatness of the second wafer W after being ground is improved.

In addition, for a third wafer W to be subjected to a grinding processing later than the second wafer W under the same conditions, the grinding processing is carried out after the shape correction operation (S3) is performed based on the measurement result of the thickness of the second wafer W by the thickness measuring device 100.

The processing in the grinding apparatus 1 according to the present exemplary embodiment is carried out as described above. Now, the setting of the shape of the wafer W to be processed in the grinding apparatus 1, which is carried out by using the above-described display panel 120, will be explained. In the following explanation, reference will be made to FIG. 5 appropriately.

First, the grinding condition of the wafer W in the grinding module 40 is input into the first input area 121 (T1 in FIG. 7). Specifically, it is input which of the chucks 42a to 42d has held the wafer W in the grinding module 40, and which of the processing positions B1 and B2 has been used to process the wafer W in the grinding module 40 (in the present exemplary embodiment, the “chuck 42a” and the “processing position B1”).

This input (T1) of the grinding condition may be omitted appropriately when the grinding module 40 has only one chuck 42 or only one grinding device, for example. Also, this input of the grinding condition may be performed manually by an operator or the like, or may be automatically input based on information, such as a recipe, which has been output from the grinding device 80 to the controller 130 in advance and stored therein.

Next, thickness values at the center point P1, the outer periphery point P2, and the radial midpoint P3 of the wafer W, which has been ground with the inclination before being corrected, are input into the first input area 121 (T2 in FIG. 7). As stated above, the thickness measurement of the wafer W after the grinding processing may be performed in the grinding device 80 or outside the grinding device 80. Also, it may be performed in the grinding apparatus 1 or outside the grinding apparatus 1.

In addition, this input (T2) of the thickness after the grinding processing may be carried out as follows: if the number of the thickness measurement points of the wafer W by the thickness measuring device 100 is less than three, it may be acceptable to input only the thickness values corresponding to the measured points, and if there are three or more measurement points, thickness values at all of those measurement points may be input. In addition, the input of the thickness after the grinding processing may be performed manually by the operator or the like, or may be automatically performed based on the information of the measurement results, which have been output from the thickness measuring device 100 to the controller 130 in advance and stored therein.

Next, a correction pattern for the grinding shape of the wafer W is input into the second input area 122 (T3 in FIG. 7). Specifically, based on the grinding shape of the wafer W before being corrected (the thickness measurement result by measuring device 100), at least one of the aforementioned grinding shape patterns (flat shape, center-convex shape, center-concave shape, W-shape and M-shape), in other words, how the grinding whetstone is to be brought into contact with the second wafer W is selected as a target grinding shape of the second wafer W to be processed using the same chuck 42 and the same grinding device in the grinding apparatus 1.

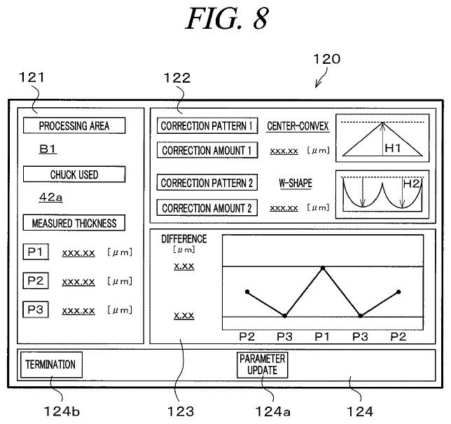

Here, when the selected correction pattern is the center-convex shape, center-concave shape, W-shape or M-shape, a correction amount (a magnitude of a thickness variation regarding the convexity or the concavity, see “H1” in FIG. 5 and FIG. 8 and “H2” in FIG. 8) is further input.

In the input (T3) of the correction pattern, a second correction pattern to be combined with a first correction pattern may be selected, as illustrated in FIG. 8. In other words, in the shape correction operation according to the present exemplary embodiment, the grinding shape of the second wafer W can be corrected from a combination of at least one or more selected correction patterns.

In addition, when the correction is performed using only the first correction pattern without combining the correction patterns, “invalid” may be selected in the second correction pattern as shown in FIG. 5.

When the input of the information into the first input area 121 and the second input area 122 is completed, the controller 130, for example, acquires an expected grinding shape and an expected flatness after the correction based on the input information, and the expected grinding shape and the expected flatness are displayed in the display area 123 (T4 in FIG. 7).

The expected grinding shape is obtained as a grinding shape pattern graph, which is prepared by connecting expected thickness values at the center point P1, the outer periphery point P2, and the radial midpoint P3 of the second wafer W in a straight line, as shown in FIG. 5 and FIG. 8. The expected flatness is obtained as a distance (difference) between a minimum thickness point and a maximum thickness point of the expected grinding shape, as shown in FIG. 5 and FIG. 8.

In the shown example, the expected grinding shape is displayed as the pattern graph which connects expected thickness values at three points in a straight line, but the display format of the expected grinding shape is not limited thereto. By way of example, instead of connecting the expected thickness values at the three points in the straight line, they may be connected in a curved line on a sine curve, or the expected thickness may be obtained and connected at three or more points.

When the expected grinding shape and flatness are displayed and it is determined that this grinding shape does not match the target grinding shape (that the grinding shape is not valid), the correction pattern and/or the correction amount is input again (T3), and a new expected grinding shape, etc., is obtained and displayed in the display area 123 (T4).

On the other hand, if it is determined that the displayed grinding shape matches the target grinding shape (that the grinding shape is valid), the parameter update section 124a in the instruction area 124 is selected (T5 in FIG. 7).

The comparison of the expected grinding shape with the target grinding shape and the suitability determination (validity determination) may be performed by the operator, or may be performed automatically by, for example, the controller 130 through numerical comparison with previously set threshold values or the like.

Likewise, the selection of the parameter update section 124a may also be performed manually by the operator, or may be performed automatically under the determination of the controller 130.

When the parameter update section 124a is selected (T5), shape correction parameters in the grinding condition (the chuck 42 and the processing position) are updated (T6 in FIG. 7). The updated parameters are output to, for example, the controller 130. The “shape correction parameters in the grinding condition” refer to parameters for the shape correction that are referred to when performing the shape correction operation for the third wafer W after the grinding processing of the second wafer W. That is, when performing the shape correction operation for the third wafer W, the expected grinding shape and/or flatness are calculated based on the parameters after the corresponding correction.

In addition, when the parameter update section 124a is selected (T5), a relative inclination between the holding surface of the chuck 42 and the grinding surface of the grinding whetstone for grinding the second wafer W with the displayed expected grinding shape and/or flatness, and a correction amount of the inclination adjusting device 44 (ascent/descent amounts of the two elevating shafts 46) for achieving this relative inclination may be further displayed.

In this case, by adjusting the relative inclination between the holding surface and the grinding surface of the grinding whetstone by the inclination adjusting device 44 based on the displayed correction amount, it is possible to obtain a grinding result with the expected grinding shape and flatness for the second wafer W.

After the shape correction parameters are updated, the termination section 124b of the instruction area 124 is selected by the operator (T7 in FIG. 7), which ends the series of setting operations on the display panel 120. These setting operations on the display panel 120 are performed for each grinding condition (combination of the chuck 42 and the grinding device) of the grinding module 40.

As described above, according to the grinding apparatus 1 of the present disclosure in the setting of the shape of the wafer W, the expected grinding shape and flatness can be output (displayed) based on the correction pattern that has been input. Then, based on this, the relative inclination between the holding surface of the chuck 42 and the grinding surface of the grinding whetstone can be adjusted by the inclination adjusting device 44, so that the required grinding result of the wafer W can be achieved.

Furthermore, according to the grinding apparatus 1 of the present disclosure, the correction pattern input into the second input area 122 is not limited to the flat shape, but can be selected from the convex shape, the concave shape, the M-shape, the W-shape, and combinations of any two of these correction patterns. That is, the grinding shape of the wafer W used for the grinding processing in the grinding apparatus 1 is not limited to the flat shape, but the wafer W can be processed into any of various grinding shapes such as the convex shape, the concave shape, the M-shape, the W-shape, and combinations of the various shapes, more specifically, the relative inclination of the holding surface and the grinding surface can be adjusted by the inclination adjusting device 44 so as to obtain the corresponding grinding shape.

In the above-described exemplary embodiment, the expected grinding shape, etc. obtained by the shape setting is fed back to the second wafer W that is processed using the same chuck 42 and the same grinding device in the grinding module 40, and the grinding shape of the second wafer W is corrected based on the expected grinding shape, etc.. However, the expected grinding shape, etc. may be fed forward to a processing performed in the grinding apparatus 1 after the grinding processing, or to processing conditions in an etching apparatus (not shown) or a polishing apparatus (not shown) which are separately provided outside the grinding apparatus 1. In other words, the expected grinding shape, etc. may be used to determine processing conditions for the grinding of the second wafer W, or may be used to determine processing conditions in a non-illustrated post-processing device for performing a post-processing on the same wafer W whose thickness, which is the basis of the shape setting, has been measured. This determination of the processing conditions may be performed by the controller 130 in one example.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

### EXPLANATION OF CODES

1: Grinding apparatus
42: Chuck
44: Inclination adjusting device
80: Grinding device
90: Grinding device
100: Thickness measuring device
120: Display panel
121: First input area
122: Second input area
123: Display area
W: Wafer

1. A grinding apparatus configured to grind a substrate, comprising:
a substrate holder configured to hold the substrate on a holding surface thereof;
a grinding device configured to grind the substrate, which is held by the substrate holder, with a grinding surface thereof;
an inclination adjusting device configured to adjust a relative inclination between the holding surface and the grinding surface; and
an information display configured to input and display information regarding shape correction of the substrate,
wherein the information display displays a display area in which an expected grinding shape of the substrate ground by the grinding device is displayed based on thickness information of the substrate before correction and correction pattern information.

2. The grinding apparatus of claim 1,
wherein the information display displays:
a first input area into which the thickness information is input; and
a second input area into which the correction pattern information is input.

3. The grinding apparatus of claim 2,
wherein the correction pattern information includes multiple correction pattern information,
the multiple correction pattern information are allowed to be input into the second input area, and
the expected grinding shape obtained by combining the multiple correction pattern information is displayed in the display area.

4. The grinding apparatus of claim 2,
wherein the thickness information of the substrate at at least three points of the substrate are allowed to be input into the first input area.

5. The grinding apparatus of claim 2,
wherein a correction amount, which is a magnitude of a thickness variation formed in a surface of the substrate by the correction pattern information is allowed to be input into the second input area.

6. The grinding apparatus of claim 2,
wherein the grinding device includes multiple grinding devices and the substrate holder includes multiple substrate holders, and
information corresponding to the grinding device and information corresponding to the substrate holder are allowed to be input into the first input area.

7. The grinding apparatus of claim 1,
wherein expected flatness of the substrate ground by the grinding device is allowed to be input in the display area.

8. The grinding apparatus of claim 1, further comprising:
a controller configured to control an operation of the inclination adjusting device,
wherein the controller adjusts the relative inclination between the holding surface and the grinding surface such that a grinding shape of a second substrate, which is to be processed next by the grinding device, matches the expected grinding shape displayed in the display area.

9. The grinding apparatus of claim 1, further comprising:
a post-processing device configured to perform a post-processing on the substrate after being ground; and
a controller configured to control an operation of the post-processing device,
wherein the controller determines a condition on the post-processing of the substrate by the post-processing device, based on the expected grinding shape.

10. An inclination adjusting method of adjusting a relative inclination between a holding surface of a substrate holder and a grinding surface of a grinding device in a grinding apparatus,
wherein the grinding apparatus comprises:
the substrate holder configured to hold a substrate on the holding surface thereof;
the grinding device configured to grind the substrate, which is held by the substrate holder, with the grinding surface thereof;
an inclination adjusting device configured to adjust the relative inclination between the holding surface and the grinding surface; and
an information display configured to input and display information regarding shape correction of the substrate, and
the inclination adjusting method comprises:
inputting thickness information of the substrate before correction and correction pattern information into the information display;
acquiring an expected grinding shape of the substrate ground by the grinding device based on the thickness information and the correction pattern information, and displaying the expected grinding shape in a display area of the information display; and
determining validity of the displayed expected grinding shape, and adjusting the relative inclination between the holding surface and the grinding surface by the inclination adjusting device.

11. The inclination adjusting method of claim 10,
wherein the inputting of the information into the information display comprises:
inputting the thickness information into a first input area; and
inputting the correction pattern information into a second input area.

12. The inclination adjusting method of claim 11,
wherein the correction pattern information includes multiple correction pattern information, and the inputting of the correction pattern information comprises inputting the multiple correction pattern information into the second input area.

13. The inclination adjusting method of claim 11,
wherein the inputting of the correction pattern information comprises inputting a correction amount, which is a magnitude of a thickness variation formed in a surface of the substrate by the correction pattern information.

14. The inclination adjusting method of claim 11,
wherein the grinding device includes multiple grinding devices and the substrate holder includes multiple substrate holders,
the grinding apparatus comprises:
the multiple grinding devices; and
the multiple substrate holders, and
information corresponding to the griding device and information corresponding to the substrate holder are input into the first input area.

15. An information display configured to display information regarding shape correction of a substrate, comprising:
a display area configured to display, based on thickness information of the substrate before correction and correction pattern information which have been input, an expected grinding shape of the substrate to be ground after the shape correction.

16. The information display of claim 15,
wherein the display area displays expected flatness of the substrate to be ground after the shape correction.

17. The information display of claim 15, further comprising:
a first input area into which the thickness information is input; and
a second input area into which the correction pattern information is input.

18. The information display of claim 17,
wherein information regarding the substrate holder holding the substrate and information regarding the grinding device grinding the substrate are input into the first input area.

19. The information display of claim 17,
where the correction pattern information includes multiple correction pattern information, and
the shape correction comprises:
inputting the thickness information of the substrate at at least three points of the substrate into the first input area;
inputting, into the second input area, at least one of the multiple correction pattern information, and a correction amount, which is a magnitude of a thickness variation formed in a surface of the substrate by the correction pattern information; and
acquiring an expected grinding shape of the substrate after correction based on the information input into the first input area and the second input area, and displaying the expected grinding shape in the display area.
